(19) United States
(12) Patent Application Publication
(10) Pub. No.: US 2025/0120225 A1
(43) Pub. Date: Apr. 10, 2025

(54) MICRO DISPLAY MODULE

(71) Applicant: JADE BIRD DISPLAY (SHANGHAI) LIMITED, SHANGHAI (CN)

(72) Inventors: Chenchao XU, Shanghai (CN); Yang YUE, Shanghai (CN); Xiaohui ZHANG, Shanghai (CN)

(21) Appl. No.: 18/910,000

(22) Filed: Oct. 9, 2024

(30) Foreign Application Priority Data
Oct. 9, 2023 (WO) PCT/CN2023/123529

(51) Int. Cl. H01L 33/44; H01L 33/58; H01L 33/62

(52) U.S. Cl. CPC H10H 20/84; H10H 20/855; H10H 20/857

(57) ABSTRACT

A micro display module includes an X-cube prism configured to combine two or more monochrome images into a polychromatic image; and at least two micro-LED (light emitting diode) display panels configured to provide the two or more monochrome images for the X-cube prism, wherein each of the micro-LED display panels is adhered to a corresponding one of surfaces of the X-cube prism.

### CROSS-REFERENCE TO RELATED APPLICATIONS

The present disclosure claims the benefits of priority to PCT Application No. PCT/CN2023/123529, filed on Oct. 9, 2023, which is incorporated herein by reference in its entirety.

### TECHNICAL FIELD

The present disclosure generally relates to the micro display field, and more particularly, to a micro display module and a micro-LED display panel.

### BACKGROUND

Micro-LEDs (light emitting diodes) with extra small area and higher resolution are increasingly popular.

A micro-LED panel with a micro-LED array can be used to form various kinds of devices, such as camera modules, projection modules, display modules, VR/AR (Virtual Reality/Augmented Reality) optical modules, and the like.

A conventional micro display module includes three micro display panels and a small X-cube prism as an optical combination unit to combine different color image light into a full color image light. A cage is needed to support the X-cube prism and the micro display panels facing the X-cube prism, so that the light emitted from the micro display panels can be transmitted into the X-cube prism.

### SUMMARY OF THE DISCLOSURE

Embodiments of the present disclosure provide a micro display module. The micro display module includes an X-cube prism configured to combine two or more monochrome images into a polychromatic image; and at least two micro-LED display panels configured to provide the two or more monochrome images for the X-cube prism, wherein each of the micro-LED displays is adhered to a corresponding one of surfaces of the X-cube prism.

Embodiments of the present disclosure also provide a micro-LED display panel. The micro-LED display panel includes a micro-LED chip provided at a first end of a flexible printed circuit (FPC) board and configured to provide a monochrome image; and a connector provided at a second end of the FPC board and configured to communicate with the micro-LED chip by the FPC board.

Many advantages and features of the present disclosure will be further understood from the following detailed description and the appended drawings.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a principle of light combination of an X-cube prism, according to some embodiments of the present disclosure.

FIG. 2 is a schematic diagram illustrating the structure of an example micro display module, according to some embodiments of the present disclosure.

FIG. 3 is an exploded view of the example micro display module shown in FIG. 2, according to some embodiments of the present disclosure.

FIG. 4 is an exploded view of another example micro display module, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

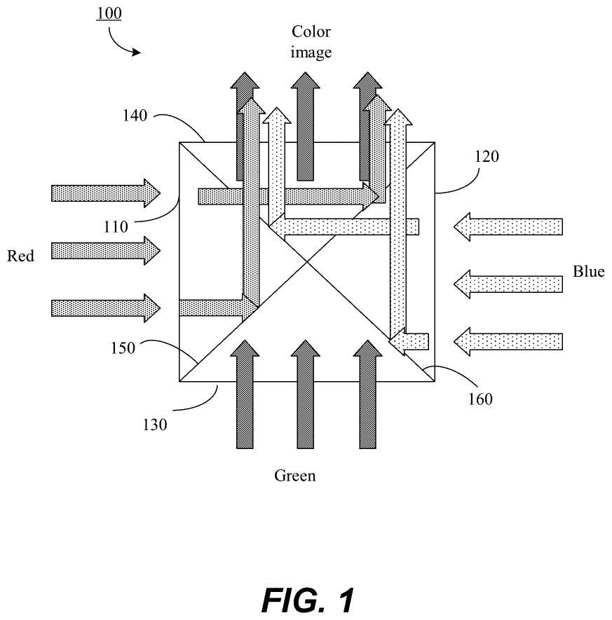

An X-cube prism is a combination of four triangular prisms with different reflective films, which is configured to combine red, green, and blue color beams to form a color image. FIG. 1 illustrates a principle of light combination of an X-cube prism 100, according to some embodiments of the present disclosure. As shown in FIG. 1, X-cube prism 100 includes three surfaces for receiving monochrome lights and one surface for transmitting light resulting from combining the monochrome lights to form a color image. For example, red light is transmitted through a first surface 110 of X-cube prism 100 and is reflected by a red reflection film 150. Blue light is transmitted through a second surface 120 of X-cube prism 100 and is reflected by a blue refection film 160. Green light is transmitted through a third surface 130 of X-cube prism 100 and can be transmitted through the X-cube prism 100 without reflection. As a result, a color image can be formed by the light transmitted from a fourth surface 140 of X-cube prism 100. With the X-cube prism 100, in order to display the color image, display panels are provided on each side of the X-cube prism by a cage. The cage is configured to support the display panels and ensure each of the display panels aligns with a corresponding surface of the X-cube prism. Because of the cage, there is a space between each of the display panels and the surfaces of the X-cube prism, which may limit a further volume decrease of a display module. Such arrangement may also cause optical loss when light is transmitted from the display panel into the X-cube.

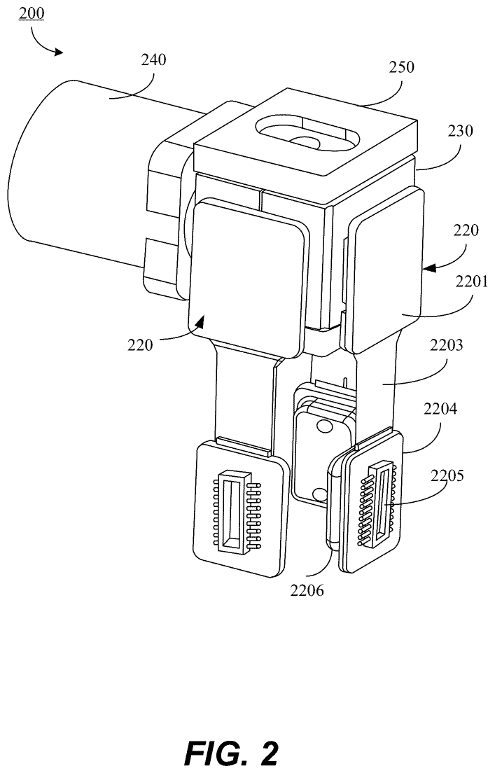

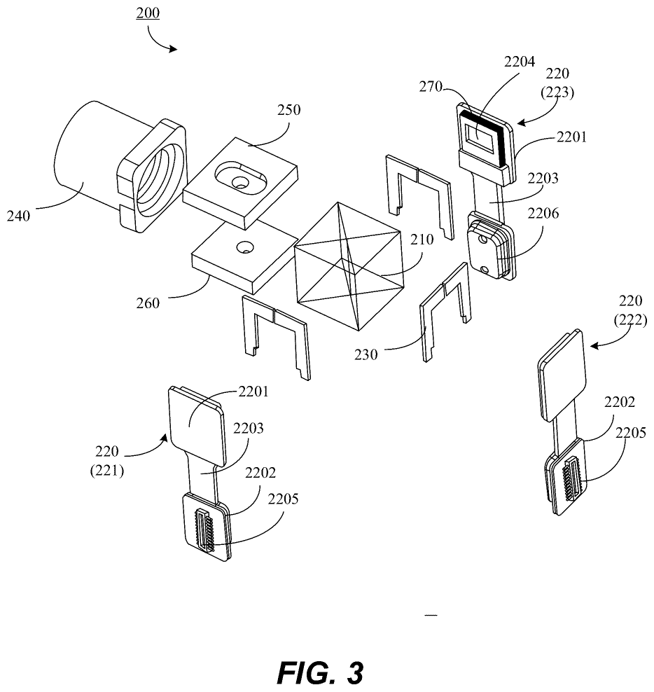

Some embodiments of the present disclosure provide a micro display module with a compact structure and high light transmission efficiency. FIG. 2 is a schematic diagram illustrating structure of an example micro display module 200, according to some embodiments of the present disclosure. FIG. 3 is an exploded view of micro display module 200, according to some embodiments of the present disclosure. Referring to FIG. 2 and FIG. 3, micro display module 200 includes an X-cube prism 210 and at least two micro-LED display panels 220. X-cube prism 210 is configured to combine two or more monochrome images into a polychromatic image. Micro-LED display panels 220 are configured to provide monochrome images. Each micro-LED display panel 220 is adhered to a surface of X-cube prism 210. Light emitted from each of micro-LED display panels 220 can be transmitted by X-cube prism 210. For example, a first micro-LED display panel 221 of display panels 220 is adhered to a first surface of X-cube prism 210. A second micro-LED display panel 222 of display panels 220 is adhered to a second surface of X-cube prism 210. A third micro-LED display panel 223 of display panels 220 is adhered to a third surface of X-cube prism 210. First micro-LED display panel 221, second micro-LED display panel 222, and third micro-LED display panel 223 are monochrome micro-LED display panels. Since micro-LED display panels 220 are adhered to the surfaces of X-cube prism 210, the space between each of micro-LED display panels 220 and a corresponding surface of X-cube prism 210 is limited. Therefore, the structure of micro display module 200 is more compact.

In some embodiments, micro display module 200 further includes a light shielding piece 230 provided on sidewalls of a corresponding one of the micro-LED display panel 220. Each light shielding piece 230 is configured to prevent light emitted from the corresponding micro-LED display panel from emitting through the sidewalls of the corresponding micro-LED display panel 220. In some embodiments, light shielding piece 230 includes two portions, and the two portions can be assembled one the sidewalls of the corresponding micro-LED display panel.

In some embodiments, each light shielding piece 230 is attached to the sidewalls of the corresponding micro-LED display panel 220. In some embodiments, an edge of each light shielding piece 230 is interior to or aligned with an edge of X-cube prism 210. That is, the edge of light shielding piece 230 does not extend from X-cube prism 210. In some embodiments, light shielding piece 230 has a U-shape structure, which includes three sides for attaching with the corresponding micro-LED display panel 220. Each side of light shielding piece 230 fits a sidewall of the corresponding micro-LED display panel 220, except the bottom side of micro-LED display panel 220. In some embodiments, a thickness of each side of light shielding piece 230 is equal to a thickness of the corresponding micro-LED display panel 220. In some embodiments, each light shielding piece 230 can be detachable from the corresponding micro-LED display panel 220.

In some embodiments, each light shielding piece 230 is non-transparent and non-reflective, which may prevent light leakage and light interference. For example, light shielding piece 230 can be black. In some embodiments, light shielding piece 230 is waterproof with chemical resistance.

In some embodiments, the sidewalls of each micro-LED display panel 220 are sealed by a light shielding layer 270. In some embodiments, light shielding layer 270 is further adhered to the surface of the X-cube prism where not covered by micro-LED display panel 220. In some embodiments, light shielding layer 270 is an anti-reflection coating layer. For example, the material of light shielding layer 270 can be black photo resist. Light shielding layer 270 can be a spin coat on the sidewalls of micro-LED display panel 220. In some embodiments, light shielding layer 270 is adhered to the sidewall surfaces of micro-LED display panel 220 by a seal glue. In some embodiments, the seal glue is non-transparent.

In some embodiments, an optical transmission film is further formed on each surface of X-cube prism 210 which faces one of micro-LED display panels 220 to improve the light transmission. In some embodiments, the optical transmittance of the optical transmission film is equal to or greater than 99% in a visible region (normally, a high optical transmittance means equal to or greater than 95%). The optical transmission film is a thin film. In some embodiments, a thickness of the optical transmission file is less than 10 μm. In some embodiments, a material of the optical transmission film is selected from at least one of resin or glue, such as ultra-violet curing adhesive.

In some embodiments, each micro-LED display panel 220 is adhered to a corresponding surface of X-cube prism 210 by an optical glue. In some embodiments, the optical glue is applied on the perimeter of micro-LED display panel 220 to adhere the micro-LED display 220 to the corresponding surface of X-cube prism 210. In some embodiments, the optical glue is an OCA (Optically Clear Adhesive) film. In some embodiments, the optical transmittance of the optical glue is equal to or greater than 95%. In some embodiments, the optical transmittance of the optical glue is equal to or greater than 99%. In some embodiments, a dispensing process of the optical glue is performed between each surface of X-cube prism 210 which faces one of micro-LED display panels 220 and a corresponding one of the micro-LED display panels 220.

In some embodiments, micro display module 200 further includes a lens 240 provided on a fourth surface of X-cube prism 210, to receive the combined lights transmitted from X-cube prism 210. Micro display module 200 further includes a top cover 250 and a bottom support 260. Top cover 250 and bottom support 260 are configured to respectively cover the top surface and bottom surface of X-cube prism 210. A material of top cover 250 and bottom support 260 can be the same as the material of light shielding piece 230.

As shown in FIG. 3, micro-LED display panel 220 further includes a micro-LED chip 2204 provided at a first end of a flexible printed circuit (FPC) board 2203 and configured to provide a monochrome image, a connector 2205 provided at a second end of FPC board 2203 and configured to communicate with micro-LED chip 2204 by FPC board 2203. In some embodiments, micro-LED chip 2204 is electrically connected to FPC board 2203 by a golden wire. Specifically, light shielding layer 270 seals sidewalls of micro-LED chip 2204 of each micro-LED display panel 220. In some embodiments, connector 2205 is further configured to electrically communicate with an external signal. Connector 2205 can be used as I/O (input/output) interface to communicate with an external device.

In some embodiments, micro-LED display panel 220 further includes a first plate 2201 connected to the first end of FPC board 2203 and a second plate 2202 connected to the second end of FPC board 2203. Micro-LED display panel 220 has a front side that faces an X- cube prism, and a back side that is the opposite side of the front side. Micro-LED chip 2204 is provided on first plate 2201 and on the front side of micro-LED display panel 220. Connector 2205 is provided on second plate 2202 and on the back side of micro-LED display panel 220. First plate 2201 and second plate 2202 can provide rigid support for micro-LED chip 2204 and connector 2205. In some embodiments, first plate 2201 is a steel plate, and second plate 2202 is a flex-rigid board, for example, a flex-rigid printed board. FPC board 2203 may include a conductive line that acts as a ground wire and couples to ground potentials of the components connected to FPC board 2203. In some embodiments, first plate 2201, FPC board 2203, and second plate 2202 are integrated into a signal structure.

In some embodiments, micro-LED chip 2204 is attached to first plate 2201 by an adhesive material, for example, a Die-Attach (DA) material. Connector 2205 is attached to second plate 2202 by an adhesive material, for example, a DA material.

In some embodiments, micro-LED display panel 220 further includes a memory chip 2206 provided on second plate 2202 and on the front side of micro-LED display panel 220. Memory chip 2206 is electrically coupled to micro-LED chip 2204 and connector 2205, and configured to cache or store patterns for displaying, or instructions for displaying patterns for micro-LED display panel 220, which may reduce the communication cost between micro-LED display panel 220 and a signal source (for example, a GPU), thereby improving display efficiency. In some embodiments, memory chip 2206 is attached to second plate 2202 by an adhesive material, for example, a DA material.

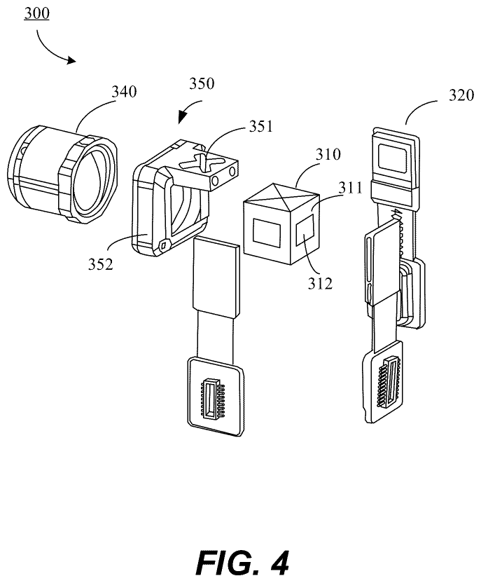

FIG. 4 illustrates an exploded view of another example micro display module 300, according to some embodiments of the present disclosure. As shown in FIG. 4, micro display module 300 includes an X-cube prism 310 and at least two micro-LED display panels 320. X-cube prism 310 is configured to combine two or more monochrome images into a polychromatic image. Micro-LED display panels 320 are configured to provide monochrome images. Each micro-LED display 320 is adhered to a corresponding surface of X-cube prism 310. In this example, three micro-LED displays 320 are provided corresponding to three surfaces of X-cube prism 310, respectively. As shown in FIG. 4, each of the three surfaces which face the three micro-LED displays 320 is partially covered by a shielding layer 311 with an opening 312 exposed corresponding to a light emitting area of the corresponding micro-LED display 320 to receive lights. In some embodiments, opening 312 has a rectangular or square shape. In some embodiments, opening 312 has a round shape. The shape of opening 312 can be determined according to a design of micro-LED display 320, which is not limit herein. In some embodiments, shielding layer 311 is provided by silkscreen printing.

Micro display module 300 further includes a lens 340 provided on a fourth surface of X-cube prism 310, to receive the combined lights transmitted from X-cube prism 310. Micro display module 300 further includes a housing 350 configured to connect lens 340 and X-cube prism 310. Housing 350 includes a top cover 351 and a lens connector 352. Top cover 351 and lens connector 352 are integrated to form housing 350. When micro display module 300 is assembled, top cover 351 can cover a top surface of X-cube prism 310, and lens connector 352 connects X-cube prism 310 with lens 340.

For the micro display module provided by the present disclosure, the micro-LED display panels are adhered to the surfaces of the X-cube prism, for example, by a glue. As a result, the structure of the micro display module is more compact. Since there is no space between each of the micro-LED display panels and the X-cube prism, there is no light leakage from the micro-LED display panels, thereby improving light transmission efficiency.

The embodiments may further be described using the following clauses:

1. A micro display module, comprising:

an X-cube prism configured to combine two or more monochrome images into a polychromatic image; and

at least two micro-LED (light emitting diode) display panels configured to provide the two or more monochrome images for the X-cube prism, wherein each of the micro-LED display panels is adhered to a corresponding one of surfaces of the X-cube prism.

2. The micro display module according to clause 1, further comprising at least one light shielding piece provided on sidewalls of corresponding one of the micro-LED display panels.

3. The micro display module according to clause 2, wherein each of the light shielding pieces is attached to the sidewall of the corresponding micro-LED display panel.

4. The micro display module according to clause 3, wherein an edge of each of the light shielding pieces is interior to or aligned with an edge of the X-cube prism.

5. The micro display module according to clause 3, wherein each of the light shielding piece comprises a U-shape structure and is attached with three sidewalls of the corresponding micro-LED display panel.

6. The micro display module according to any one of clause 2 to 5, wherein each of the light shielding pieces comprises one or more of following properties: non-transparent, non-reflected, waterproof, or chemical resistance.

7. The micro display module according to clause 6, wherein each of the light shielding pieces is black.

8. The micro display module according to clause 1, wherein sidewalls of the micro-LED display panels are sealed by a light shielding layer.

9. The micro display module according to clause 8, wherein the light shielding layer is further adhered to the X-cube prism by a seal glue.

10. The micro display module according to clause 9, wherein the seal glue is non-transparent.

11. The micro display module according to clause 1, wherein the each of the micro-LED display panels is adhered to the corresponding surface of the X-cube prism by an optical transmission film.

12. The micro display module according to clause 11, wherein an optical transmittance of the optical transmission film is equal to or greater than 99%.

13. The micro display module according to clause 12, wherein a material of the optical transmission film is selected from at least one of resin or glue.

14. The micro display module according to clause 13, wherein the material of the optical transmission film is ultra-violet curing adhesive.

15. The micro display module according to clause 1, wherein each of the micro-LED display panels is adhered to the corresponding surface of the X-cube prism by an optical glue.

16. The micro display module according to clause 15, wherein the optical glue is applied on a perimeter of each of the micro-LED display panels.

17. The micro display module according to clause 16, wherein the optical glue is applied by a dispensing process to adhere each of the micro-LED display panels to the corresponding surface of the X-cube prism.

18. The micro display module according to clause 15, wherein the optical glue is an OCA (Optically Clear Adhesive) film.

19. The micro display module according to clause 1, wherein the micro-LED display panels are adhered to corresponding ones of surfaces of the X-cube, the micro display module further comprises a lens provided on a second surface of the X-cube prism to receive lights transmitted from the X-cube prism.

20. The micro display module according to clause 19, further comprising a housing configured to connect the lens with the X-cube prism.

21. The micro display module according to clause 20, wherein the housing comprises:

a top cover configured to cover a top surface of the X-cube prism; and

a lens connector configured to connect the lens with the X-cube prism, wherein the top cover and the lens connector are integrated.

22. The micro display module according to clause 1, wherein each of the surfaces of the X-cube prism to which a corresponding one of the micro-LED display panels is adhered is covered by a shielding layer with an opening exposed and corresponding to a light emitting area of the corresponding micro-LED display panel.

23. A micro-LED display panel, comprising:

a micro-LED chip provided at a first end of a flexible printed circuit (FPC) board and configured to provide a monochrome image; and

a connector provided at a second end of the FPC board and configured to communicate with the micro-LED chip by the FPC board.

24. The micro-LED display panel according to clause 23, wherein the connector is further configured to electrically communicate with an external signal.

25. The micro-LED display panel according to clause 23, further comprising:

a first plate connected to the first end of the FPC, wherein the micro-LED chip is provided on the first plate and on a front side of the micro-LED display panel; and

a second plate connected to the second end of the FPC board, wherein the connector is provided on the second plate and on a back side of the micro-LED display panel.

26. The micro-LED display panel according to clause 25, wherein the micro-LED chip is attached to the first plate by an adhesive material.

27. The micro-LED display panel according to clause 25, wherein the connector is attached on the second plate by an adhesive material.

28. The micro-LED display panel according to clause 26 or 27, wherein the adhesive material is a Die-Attach (DA) material.

29. The micro-LED display panel according to clause 25, wherein the micro-LED chip is electrically connected to the FPC board by a golden wire.

30. The micro-LED display panel according to clause 25, further comprising:

a memory chip provided on the second plate and on the front side of the micro-LED display panel and electrically coupled to the micro-LED chip and the connector.

31. The micro-LED display panel according to clause 30, wherein the memory chip is attached to the second plate by an adhesive material.

32. The micro-LED display panel according to clause 31, wherein the adhesive material is a Die-Attach (DA) material.

33. The micro-LED display panel according to clause 25, wherein the first plate is a steel plate, and the second plate is a flex-rigid board.

34. The micro-LED display panel according to clause 25, wherein the first plate, the FPC board, and the second plate are integrated into a signal structure.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro display module, comprising:
an X-cube prism configured to combine two or more monochrome images into a polychromatic image; and
at least two micro-LED (light emitting diode) display panels configured to provide the two or more monochrome images for the X-cube prism, wherein each of the micro-LED display panels is adhered to a corresponding one of surfaces of the X-cube prism.

2. The micro display module according to claim 1, further comprising at least one light shielding piece provided on sidewalls of corresponding one of the micro-LED display panels.

3. The micro display module according to claim 2, wherein each of the light shielding pieces is attached to the sidewall of the corresponding micro-LED display panel.

4. The micro display module according to claim 3, wherein an edge of each of the light shielding pieces is interior to or aligned with an edge of the X-cube prism.

5. The micro display module according to claim 3, wherein each of the light shielding piece comprises a U-shape structure and is attached with three sidewalls of the corresponding micro-LED display panel.

6. The micro display module according claim 2, wherein each of the light shielding pieces comprises one or more of following properties: non-transparent, non-reflected, waterproof, or chemical resistance.

7. The micro display module according to claim 6, wherein each of the light shielding pieces is black.

8. The micro display module according to claim 1, wherein sidewalls of the micro-LED display panels are sealed by a light shielding layer.

9. The micro display module according to claim 8, wherein the light shielding layer is further adhered to the X-cube prism by a seal glue.

10. The micro display module according to claim 9, wherein the seal glue is non-transparent.

11. The micro display module according to claim 1, wherein the each of the micro-LED display panels is adhered to the corresponding surface of the X-cube prism by an optical transmission film.

12. The micro display module according to claim 11, wherein an optical transmittance of the optical transmission film is equal to or greater than 99%.

13. The micro display module according to claim 12, wherein a material of the optical transmission film is selected from at least one of resin or glue.

14. The micro display module according to claim 13, wherein the material of the optical transmission film is ultra-violet curing adhesive.

15. The micro display module according to claim 1, wherein each of the micro-LED display panels is adhered to the corresponding surface of the X-cube prism by an optical glue.

16. The micro display module according to claim 15, wherein the optical glue is applied on a perimeter of each of the micro-LED display panels.

17. The micro display module according to claim 16, wherein the optical glue is applied by a dispensing process to adhere each of the micro-LED display panels to the corresponding surface of the X-cube prism.

18. The micro display module according to claim 15, wherein the optical glue is an OCA (Optically Clear Adhesive) film.

19. The micro display module according to claim 1, wherein the micro-LED display panels are adhered to corresponding ones of surfaces of the X-cube, the micro display module further comprises a lens provided on a second surface of the X-cube prism to receive lights transmitted from the X-cube prism.

20. The micro display module according to claim 19, further comprising a housing configured to connect the lens with the X-cube prism.

21. The micro display module according to claim 20, wherein the housing comprises:
a top cover configured to cover a top surface of the X-cube prism; and
a lens connector configured to connect the lens with the X-cube prism, wherein the top cover and the lens connector are integrated.

22. The micro display module according to claim 1, wherein each of the surfaces of the X-cube prism to which a corresponding one of the micro-LED display panels is adhered is covered by a shielding layer with an opening exposed and corresponding to a light emitting area of the corresponding micro-LED display panel.

23. A micro-LED display panel, comprising:
a micro-LED chip provided at a first end of a flexible printed circuit (FPC) board and configured to provide a monochrome image; and
a connector provided at a second end of the FPC board and configured to communicate with the micro-LED chip by the FPC board.

24. The micro-LED display panel according to claim 23, wherein the connector is further configured to electrically communicate with an external signal.

25. The micro-LED display panel according to claim 23, further comprising:
a first plate connected to the first end of the FPC, wherein the micro-LED chip is provided on the first plate and on a front side of the micro-LED display panel; and
a second plate connected to the second end of the FPC board, wherein the connector is provided on the second plate and on a back side of the micro-LED display panel.

26. The micro-LED display panel according to claim 25, wherein the micro-LED chip is attached to the first plate by an adhesive material.

27. The micro-LED display panel according to claim 25, wherein the connector is attached on the second plate by an adhesive material.

28. The micro-LED display panel according to claim 26, wherein the adhesive material is a Die-Attach (DA) material.

29. The micro-LED display panel according to claim 25, wherein the micro-LED chip is electrically connected to the FPC board by a golden wire.

30. The micro-LED display panel according to claim 25, further comprising:
a memory chip provided on the second plate and on the front side of the micro-LED display panel and electrically coupled to the micro-LED chip and the connector.

31. The micro-LED display panel according to claim 30, wherein the memory chip is attached to the second plate by an adhesive material.

32. The micro-LED display panel according to claim 31, wherein the adhesive material is a Die-Attach (DA) material.

33. The micro-LED display panel according to claim 25, wherein the first plate is a steel plate, and the second plate is a flex-rigid board.

34. The micro-LED display panel according to claim 25, wherein the first plate, the FPC board, and the second plate are integrated into a signal structure.
